(19) United States
(12) Patent Application Publication
(10) Pub. No.: US 2008/0241709 A1
(43) Pub. Date: Oct. 2, 2008

(54) System And Method For analyzing photomask Geometries

(76) Inventors: Kent Nakagawa, Beaverton, OR (US); Peter Buck, Aloha, OR (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/695,416

(22) Filed: Apr. 2, 2007

(51) Int. Cl. G03F 1/14

(52) U.S. Cl. 430/5; 716/19

(57) ABSTRACT

In one embodiment, a method for analyzing photomask geometries is provided. An original geometry to be formed in an absorber layer of a photomask blank is received. The original geometry may be modified to generate a modified geometry that is offset from the original geometry. A simulation may be performed based on the modified geometry to determine a simulated geometry, wherein the simulated geometry is a simulated prediction of a geometry that would be written into a resist layer of the photomask blank if the modified geometry was used as input for imaging the resist layer. The simulated geometry may then be modified to determine a predicted original geometry, wherein the predicted original geometry is a prediction of a geometry that would be formed in the absorber layer of the photomask blank if an etch process was performed on an area of the absorber layer defined by the simulated geometry.

### CROSS REFERENCE TO RELATED APPLICATION

This application is a continuation of International Patent Application No. US2005/035737 filed Oct. 5, 2005, which designates the United States and claims priority from U.S. Provisional Patent Application Ser. No. 60/615,881, filed Oct. 5, 2004, by Kent Nakagawa et al., entitled “Systems and Methods for Predicting Photomask Geometries Using Simulation” which is hereby incorporated in its entirety by reference.

### TECHNICAL FIELD

The present disclosure relates in general to integrated circuit fabrication and, more particularly, to a system and method for analyzing photomask geometries.

### BACKGROUND

Integrated circuit devices typically include various circuit components, such as transistors, resistors and capacitors. These integrated circuit components may be produced by forming particular geometries in a semiconductor wafer (e.g., a silicon wafer) using various integrated circuit fabrication techniques, including lithography techniques using one or more photomasks, for example.

Photomasks themselves may be formed from photomask blanks using various lithography processes. A mask pattern file that defines one or more geometries to be formed in an absorber layer of the photomask blank may be used as input by a pattern-imaging tool, such as a laser system, an electron beam system, or an X-ray lithography system. The pattern-imaging tool may be used to expose portions of a resist layer formed over the absorber layer of the photomask blank corresponding with the geometries defined by the mask pattern file.

However, the accuracy of the geometries actually imaged onto the resist layer (as compared with the geometries defined by the mask pattern file) may be limited by the particular pattern-imaging tools being used. For example, where an electron beam or laser is used to transfer the pattern into the resist layer, the acuity or sharpness of particular geometries imaged into the resist layer may be limited by the width of the electron or laser beam being used. Thus, due to distortion caused by the physical limitations of imaging tools, particular geometries defined by the mask pattern file may not be transferred into the resist layer of the photomask with sufficient or desired accuracy.

FIG. 1 illustrates an example geometry 10 defined by a mask pattern file, and a corresponding geometry 12 actually imaged into the resist layer of the photomask, where the differences between geometry 10 and geometry 12 are caused by the physical limitations of the pattern-imaging tool being used. As shown in FIG. 1, due to the limitations of the pattern-imaging tool, the corners of imaged geometry 12 are rounded. The degree of corner-rounding is a function of the pattern-imaging tool being used, such as the width of the electron beam or laser being used.

Once the pattern defined by the mask pattern file is imaged into the resist layer of the photomask, the exposed areas of the resist layer are developed and etched to create a pattern in the resist layer. Portions of the underlying absorber layer of the photomask blank that are not covered by resist (e.g., exposed areas) are then etched, and the undeveloped portions of the resist layer may then be removed to create the desired pattern (or an approximation of the desired pattern) in the absorber layer. During the etching of exposed areas of the absorber layer, additional portions of the absorber layer beyond the edges of the exposed areas may also be etched. Such additional etching may be referred to as “over-etch.” Thus, when an etch process is performed on an exposed area of the absorber layer having a particular geometry, the actual portion of the absorber layer removed by the etch process may have a different, e.g., more inclusive, geometry. For example, where the over-etch is relatively uniform around the perimeter of the geometry of the portion of the absorber layer being etched, the geometry of the actual portion of the absorber layer removed by the etch process may have a perimeter that is uniformly offset from the geometry of the exposed area of the opaque layer.

Continuing the example shown in FIG. 1, FIG. 2 illustrates example geometry 12 imaged into the resist layer of the photomask blank and an example geometry 14 formed in the absorber layer of the photomask blank by the etching process discussed above. As shown in FIG. 2, the perimeter of geometry 14 actually formed in the absorber layer is offset from the perimeter of geometry 12 imaged into the resist layer due to the effects of over etching. This over-etch may be caused by various factors, such as undercut of the resist layer during a wet etch process or erosion of the resist layer during a dry etch process.

FIG. 3 illustrates an example effect of over etching at a corner region 16 of geometries 10, 12 and 14 shown in FIGS. 1 and 2. The offset caused by the over etching effects may have a generally uniform distance, D, in a direction perpendicular to the edge of geometry 12 at each point along the edge of geometry 12, as indicated by uniform-length arrows 18. As shown, arrows 18 each extend in a direction perpendicular to its respective location along the edge of geometry 12. Since the change in edge position is perpendicular to each point on the edge of geometry 12, the effect is a change of curvature at the corners and other non-linear portions of geometry 12. Thus, the curvature of geometry 14 at corner region 16 is different from the curvature of geometry 12 at corner 16. In particular, the curvature of inside corner 20 of geometry 14 may become less sharp (or less acute), while the curvature of outside corner 22 of geometry 14 may become sharper (or more acute).

The absorber layer of the photomask, which may also be referred to as the patterned layer, may include one or more components that have geometries that correspond to integrated circuit (IC) components to be formed on a semiconductor wafer. During a lithography process, the patterned layer, which includes geometries for the IC components, is transferred onto a surface of a semiconductor wafer to form the corresponding IC components. These IC components may include, but are not limited to, resistors, transistors, capacitors, interconnects, vias, and metal lines, for example.

In some situations, it is important or critical to the proper operation of the resulting IC that particular IC components are formed with precision and/or accuracy. Thus, it would be desirable to be able to predict the resulting geometry that is actually formed in the absorber (or patterned) layer of the photomask based on a particular geometry defined in the mask pattern file. In particular, it would be desirable that such prediction would account for both (1) differences between geometries defined in the mask pattern file and the corresponding geometries actually imaged into the resist layer of the photomask blank, where the differences may be caused by the physical limitations of the pattern-imaging tool being used, and (2) differences between the geometries imaged into the resist layer of the photomask and the corresponding geometries actually formed in the absorber (or patterned) layer of the photomask, where the differences may be caused by over etching.

### SUMMARY

In accordance with teachings of the present disclosure, disadvantages and problems associated with predicting and/or analyzing photomask geometries have been substantially reduced or eliminated.

In a particular embodiment, a method for analyzing photomask geometries is provided. An original geometry to be formed in an absorber layer of a photomask blank is received. The original geometry may be modified to generate a modified geometry that is offset from the original geometry in at least one direction. A simulation may be performed based on the modified geometry to determine a simulated geometry, wherein the simulated geometry is a simulated prediction of a geometry that would be written into a resist layer of the photomask blank if the modified geometry was used as input for imaging the resist layer. The simulated geometry may then be modified to determine a predicted original geometry, wherein the predicted original geometry is a prediction of a geometry that would be formed in the absorber layer of the photomask blank if an etch process was performed on an area of the absorber layer defined by the simulated geometry.

In another embodiment, a system for analyzing photomask geometries is provided. The system may include a computer system having a processor and a computer-readable medium interfaced with the computer system. The computer-readable medium may include software that, when executed by the processor, is operable to: receive an original geometry to be formed in an absorber layer of a photomask blank; modify the original geometry to generate a modified geometry, the modified geometry including a geometry offset from the original geometry in at least one direction; perform a simulation based on the modified geometry to determine a simulated geometry, the simulated geometry including a simulated prediction of a geometry that would be written into a resist layer of the photomask blank if the modified geometry was used as input for imaging the resist layer; and modify the simulated geometry to generate a predicted original geometry, the predicted original geometry including a prediction of a geometry that would be formed in the absorber layer of the photomask blank if an etch process was performed on an area of the absorber layer defined by the simulated geometry.

One advantage of at least some embodiments of the present disclosure is that systems and methods are provided for predicting a resulting geometry that would be formed in an absorber layer of a photomask blank to form a patterned layer of a photomask if a particular geometry was used as input for the formation of the patterned layer. Geometries defined by a mask pattern file may be simulated prior to actually forming a patterned layer on a photomask in order to predict the actual pattern that would be formed in the patterned layer if the mask pattern file were used as input. Based on the results of such simulations, the mask pattern file may be adjusted until a suitable predicted actual pattern is determined. This may reduce or eliminate the likelihood of forming a patterned layer on a production photomask that is undesirable due to differences between the geometries defined by the mask pattern file used to generate the patterned layer and the geometries actually formed in the patterned layer (e.g., where the differences are due to factors such as dimensional limitations inherent in the tools used to generate the patterned layers, and/or the effect of over etching). Thus, time and expenses associated with forming undesirable photomasks (which may need to be discarded) may be reduced or eliminated. In some embodiments, the simulations may be performed using a computer system.

All, some, or none of these technical advantages may be present in various embodiments of the present disclosure. Other technical advantages will be readily apparent to one skilled in the art from the following figures, descriptions, and claims.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates an example geometry defined in a mask pattern file and a corresponding geometry actually imaged into the resist layer of a photomask blank using the mask pattern file as input;

FIG. 2 illustrates the example geometry defined in the mask pattern file, the corresponding geometry actually imaged into the resist layer as shown in FIG. 1, and an example geometry actually formed in the absorber layer of the photomask blank after an etch process is performed;

FIG. 3 illustrates an example effect of over etching at a particular corner of the geometries shown in FIGS. 1 and 2;

FIG. 4 illustrates a cross-sectional view of an example photomask assembly formed, according to certain embodiments of the present disclosure;

FIGS. 5A-5C illustrate an example method for predicting a resulting geometry that will be used to form a patterned layer of a photomask based on a particular geometry defined by a mask pattern file, in accordance with a particular embodiment of the disclosure;

FIG. 6 illustrates a comparison between a predicted resulting geometry generated according to the method shown in FIGS. 5A-5C and a conventional predicted geometry;

FIG. 7 is a detailed view of a first corner region of the comparison between the predicted resulting geometry and the conventional predicted geometry shown in FIG. 6;

FIG. 8 is a detailed view of a second corner region of the comparison between the predicted resulting geometry and the conventional predicted geometry shown in FIG. 6;

FIG. 9 illustrates an example system for predicting a resulting geometry that will be used to form a patterned layer of a photomask based on a particular geometry defined by a mask pattern file, in accordance with a particular embodiment of the present disclosure; and

FIG. 10 illustrates a flow chart of a method for forming a patterned layer on a photomask, according to one embodiment of the present disclosure.

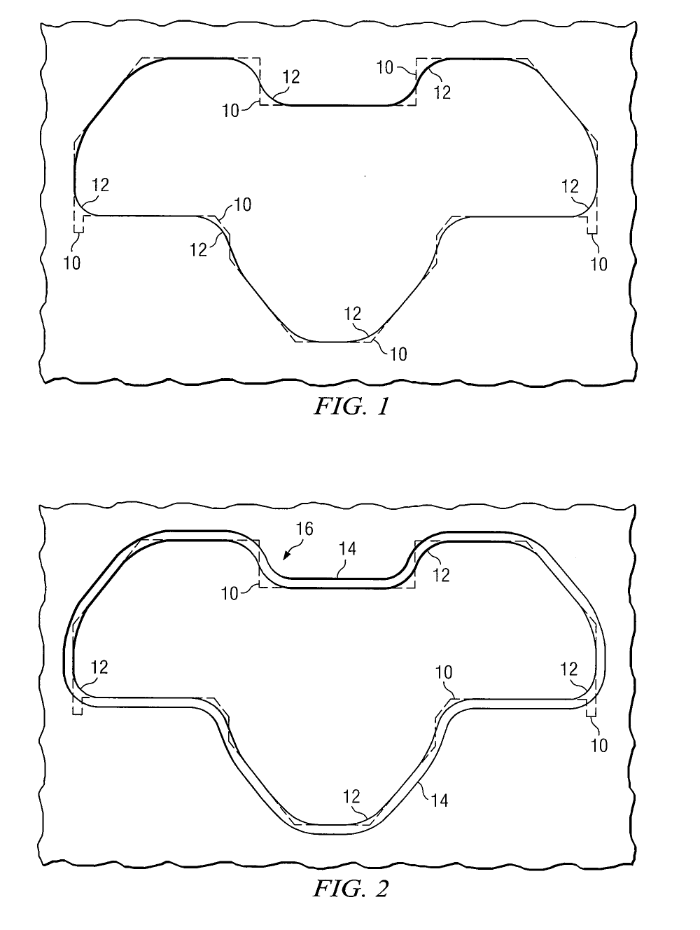

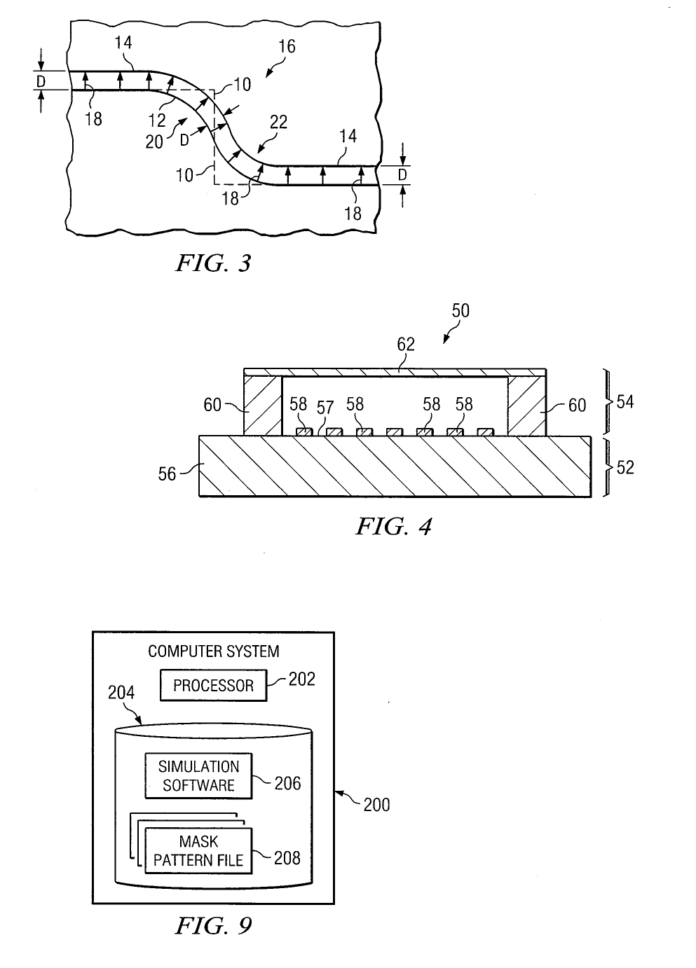

### DETAILED DESCRIPTION OF THE DRAWINGS

Various embodiments of the present disclosure and their advantages are best understood by reference to FIGS. 4 through 10, where like numbers are used to indicate like and corresponding parts.

FIG. 4 illustrates a cross-sectional view of an example photomask assembly 50 according to certain embodiments of the present disclosure. Photomask assembly 50 may include a pellicle assembly 54 mounted on a photomask 52. A substrate 56 and a patterned layer 58 may form photomask 52, otherwise known as a mask or reticle, that may have a variety of sizes and shapes, including, but not limited to, round, rectangular, or square. Photomask 52 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer. Photomask 52 may further be a binary mask, a phase shift mask (PSM) (e.g., an alternating aperture phase shift mask, also known as a Levenson type mask), an optical proximity correction (OPC) mask or any other type of mask suitable for use in a lithography system.

Patterned layer 58 of photomask 52 may be formed on a surface 57 of substrate 56 that, when exposed to electromagnetic energy in a lithography system, projects a pattern onto a surface of a semiconductor wafer (not expressly shown). Substrate 56 may be a transparent material such as quartz, synthetic quartz, fused silica, magnesium fluoride (MgF₂), calcium fluoride (CaF₂), or any other suitable material that transmits at least seventy-five percent (75%) of incident light having a wavelength between approximately 10 nm and approximately 450 nm. In an alternative embodiment, substrate 56 may be a reflective material such as silicon or any other suitable material that reflects greater than approximately fifty percent (50%) of incident light having a wavelength between approximately 10 nm and 450 nm.

Patterned layer 58 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), for example, or any other suitable material that absorbs electromagnetic energy with wavelengths in the ultraviolet (UV) range, deep ultraviolet (DUV) range, vacuum ultraviolet (VUV) range and extreme ultraviolet range (EUV). In an alternative embodiment, patterned layer 58 may be a partially transmissive material, e.g., molybdenum silicide (MoSi), which has a transmissivity of approximately one percent (1%) to approximately thirty percent (30%) in the V, DUV, VUV and EUV ranges.

A frame 60 and a pellicle film 62 may form pellicle assembly 54. Frame 60 is typically formed of anodized aluminum, although it could alternatively be formed of stainless steel, plastic or other suitable materials that do not degrade or outgas when exposed to electromagnetic energy within a lithography system. Pellicle film 62 may be a thin film membrane formed of a material such as, for example, nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the V, DUV, EUV and/or VUV ranges. Pellicle film 62 may be prepared by a conventional technique such as spin casting, for example.

Pellicle film 62 may protect photomask 52 from contaminants, such as dust particles, by ensuring that the contaminants remain a defined distance away from photomask 52. This may be especially important in a lithography system. During a lithography process, photomask assembly 50 may be exposed to electromagnetic energy produced by a radiant energy source within the lithography system. The electromagnetic energy may include light of various wavelengths, e.g., wavelengths approximately between the I-line and G-line of a Mercury arc lamp, or DUV, VUV or EUV light. In operation, pellicle film 62 may be designed to allow a large percentage of the electromagnetic energy to pass through it. Contaminants collected on pellicle film 62 will likely be out of focus at the surface of the wafer being processed and, therefore, the exposed image on the wafer should be clear. Pellicle film 62 formed in accordance with the teachings of the present disclosure may be satisfactorily used with all types of electromagnetic energy and is not limited to lightwaves as described in this application.

Photomask 52 may be formed from a photomask blank using a standard lithography process. In a lithography process, a mask pattern file that includes data for patterned layer 58 may be generated from a mask layout file. The mask layout file may define one or more geometries, which may include polygons or other shapes that represent various IC components, such as transistors, resistors, capacitors, vias and interconnects, for example. The geometries defined by the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may define one or more polygons drawn on the diffusion layer and one or more polygons drawn on the polysilicon layer. The polygons for each layer may be converted into a mask pattern file that represents one layer of the integrated circuit. Each mask pattern file may be used to generate a photomask for the specific layer. In some embodiments, the mask pattern file may define more than one layer of the integrated circuit such that a photomask may be used to image features from more than one layer onto the surface of a semiconductor wafer.

Using the mask pattern file(s) as input, the desired pattern for patterned layer 58 may be imaged into a resist layer of the photomask blank using a laser, electron beam, X-ray lithography system, or other suitable pattern-imaging tools. The imaged portions of the resist layer may be referred to as “exposed” areas. In one embodiment, a laser lithography system uses an Argon-Ion laser that emits light having a wavelength of approximately 364 nm. In other embodiments, the laser lithography system uses lasers emitting light at wavelengths from approximately 150 nm to approximately 300 nm.

As discussed above, the accuracy of imaging the geometries defined by the mask pattern file(s) into the resist layer may be limited by the particular pattern-imaging tools being used. For example, where an electron beam or laser is used to transfer the pattern into the resist layer, the acuity or sharpness of particular geometries that may be imaged into the resist layer may be limited by the width of the electron or laser beam being used. Thus, due to distortion caused by the physical limitations of imaging tools, particular geometries within the pattern defined by the mask pattern file(s) may not be transferred into the resist layer of photomask 52 with sufficient or desired accuracy.

Once the pattern defined by the mask pattern file(s) is imaged into the resist layer, the exposed areas of the resist layer may be developed and etched away to create a pattern in the resist layer. Portions of the underlying patterned layer 58 not covered by resist may then be etched, and the undeveloped portions of the resist layer may then be removed to create the desired pattern (or at least an approximation of the desired pattern) in patterned layer 58 over substrate 56. In some situations, additional portions beyond the edges of the exposed areas may also be etched, which may be referred to as “over etching.”

In order to eliminate distortion caused by the physical limitations of the tools and/or the effects of over etching, the pattern (or portions thereof) defined by the mask pattern file(s) may be simulated prior to actually forming patterned layer 58 on photomask 52 such that the actual pattern that will be formed in patterned layer 58 may be predicted. Based on the results of the simulations, the mask pattern file(s) may be adjusted until a suitable predicted actual pattern is determined. This may reduce or eliminate the likelihood of forming patterned layers 58 on photomasks 52 that are undesirable due to differences between the geometries in the pattern defined by the mask layout file(s) used to generate such patterned layers 58 and the geometries actually resulting in such patterned layers 58 (e.g., due to factors such as dimensional limitations inherent in the equipment used to generate patterned layers 58, the effects of over etching, etc.).

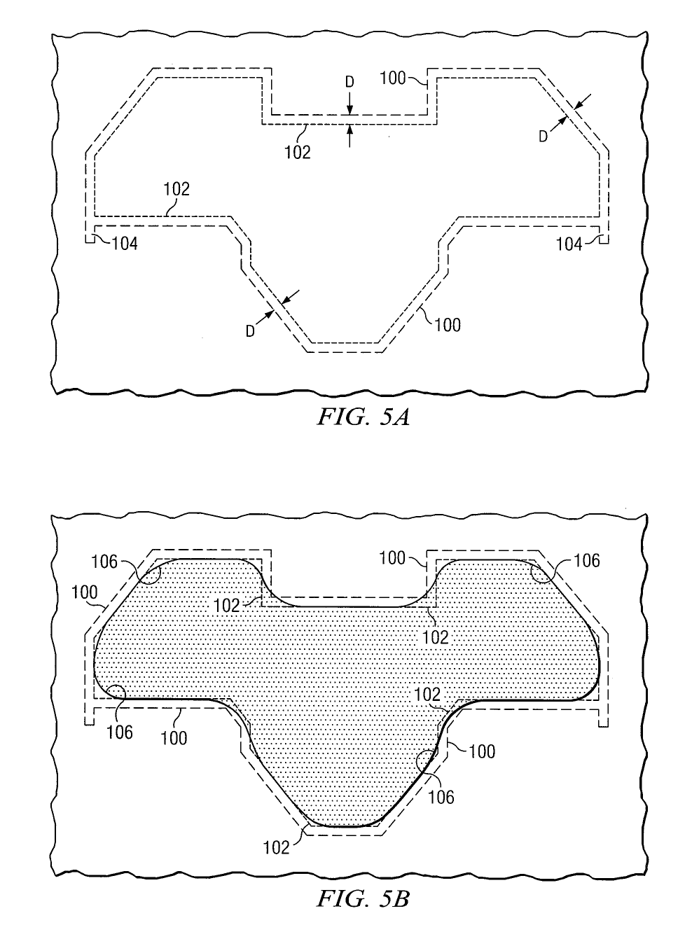

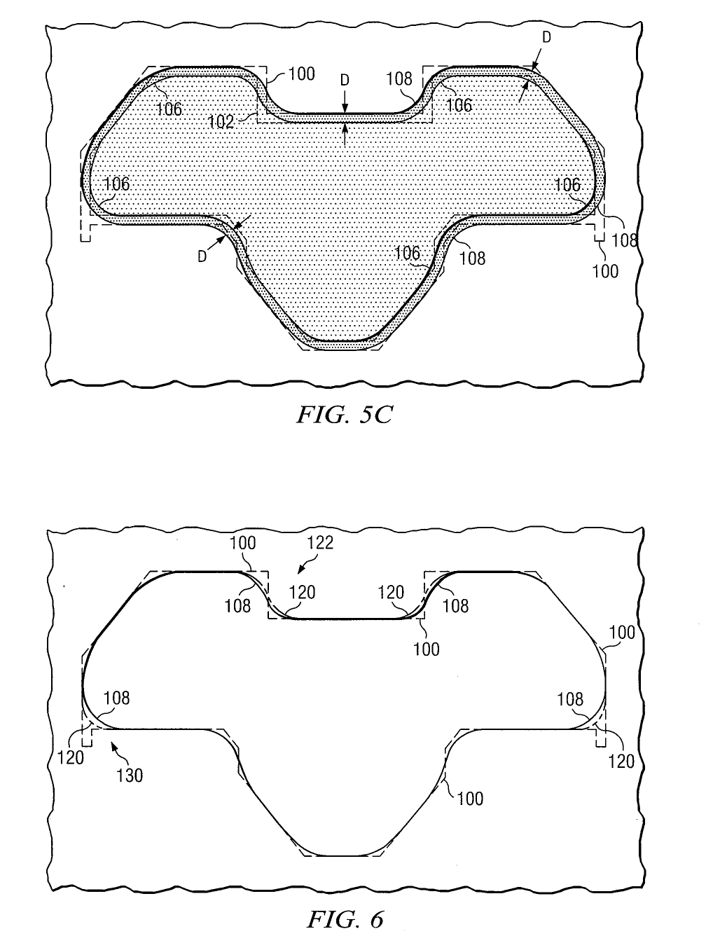

FIGS. 5A-5C illustrate an example method for predicting a resulting geometry that will be formed in a patterned layer 58 of a photomask 52 based on a particular geometry defined by a mask pattern file in accordance with a particular embodiment of the disclosure. FIG. 5A illustrates a desired geometry 100 defined by a mask pattern file. Desired geometry 100 is a geometry intended to be formed in one or more semiconductor wafers, and may correspond with one or more components of an integrated circuit to be formed in the semiconductor wafers.

Desired geometry 100 may be modified by a particular offset extending around the perimeter of desired geometry 100 to generate a modified geometry 102. The width or distance, D, of the offset may be completely, or at least substantially, uniform around the perimeter of desired geometry 100. In certain embodiments, the width or distance, D, of the offset is determined based on an expected distance of over-etch associated with an etch process that may be used (or that may be expected to be used) to form the geometry in patterned layer 58 during the formation of photomask 52. For example, if an over-etch of 30 nm is known to result when a particular etch process is used to form patterned layer 58 in photomask 52, an offset of D=30 nm may be used to generate modified geometry 102. As shown in FIG. 5A, one or more particular features 104 (e.g., relatively small features) of desired geometry 100 may be lost in the generation of modified geometry 102 due to the offset extending around the perimeter of modified geometry 102.

After generating modified geometry 102 having an offset of distance D from desired geometry 100, a computerized simulation based on modified geometry 102 may be performed to determine a simulated geometry 106, as indicated in FIG. 5B. Simulated geometry 106 represents a simulated prediction of the geometry that would be written onto photomask 52 if modified geometry 102 was used as input by a pattern-imaging tool, such as a laser imaging tool, an electron beam imaging tool, or an X-ray lithography system, for example. For instance, the simulation may attempt to predict corner-rounding and other effects associated with imaging a particular geometry (in this case, modified geometry 102). The simulation may include any one or more suitable algorithms or modeling functions, such as one or more Gaussian functions or expressions. In some embodiments, a Gaussian spot size may be calibrated to correspond with a particular imaging tool, such as an ALTA laser writer (e.g., the ALTA4000 tool) or a JEOL e-beam tool. The simulation may be performed or facilitated using any suitable software applications, such as the CALIBRE™ modeling software available from Mentor Graphics Corporation™.

After simulated geometry 106 has been generated, simulated geometry 106 may be modified to generate a predicted resulting geometry 108. Predicted resulting geometry 108 includes a prediction of the geometry that would be formed in patterned layer 58 of photomask 52 if photomask 52 were processed using modified geometry 102 as input for imaging the resist layer of the photomask blank used to create photomask 52. In other words, predicted resulting geometry 108 includes a prediction of the geometry that would be formed in patterned layer 58 if an etch process was performed on an area of patterned layer 58 defined by simulated geometry 106. Thus, predicted resulting geometry 108 may account for the geometric offset predicted to result due to over-etch if simulated geometry 106 were etched into patterned layer 58. As shown in FIG. 5C, the offset, which may extend around the perimeter of simulated geometry 106, may have a uniform width, or distance, D.

As show in FIG. 5C, linear portions of predicted resulting geometry 108 (more particularly, linear portions that are not adjacent a corner region of desired geometry 100) may substantially match corresponding linear portions of desired geometry 100. This results from the fact that linear portions of modified geometry 102 are offset inwardly from desired geometry 100 by distance D, linear portions of simulated geometry 104 (or at least linear portions that are not adjacent a corner region) substantially match corresponding linear portions of modified geometry 102 being simulated, and linear portions of predicted resulting geometry 108 are offset outwardly form simulated geometry 104 by distance D. Thus, the inward and outward offsets of distance D may essentially cancel each other.

FIG. 6 illustrates a comparison between predicted resulting geometry 108 generated according to the method shown in FIGS. 5A-5C and a conventional predicted geometry 120. Like predicted resulting geometry 108, conventional predicted geometry 120 represents a predicted geometry that would be formed in patterned layer 58 of photomask 52 if photomask 52 were processed using modified geometry 102 as input for imaging the resist layer of photomask 52 (as discussed above). However, unlike predicted resulting geometry 108, conventional predicted geometry 120 is generated using known simulation models or other known techniques, such as by applying one or more Gaussian functions or expressions directly to desired geometry 100.

In at least some situations, predicted resulting geometry 108 is a substantially accurate simulated approximation of the geometry that would be formed in patterned layer 58 of photomask 52 if modified geometry 102 was used as input for imaging the resist layer of photomask 52. In at least some situations, predicted resulting geometry 108 is a more accurate approximation of the actual resulting geometry that would be formed in patterned layer 58 of photomask 52 than prior simulated geometries, such as conventional predicted geometry 120, for example.

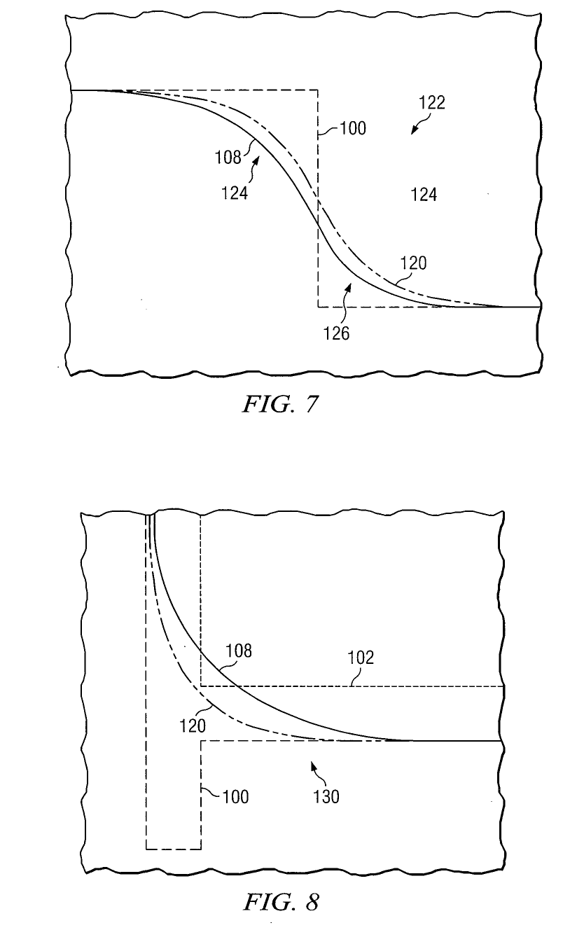

FIG. 7 is a detailed view of a first corner region 122 of the comparison between predicted resulting geometry 108 and conventional predicted geometry 120 shown in FIG. 6. As shown in FIG. 7, the curved portion of conventional predicted geometry 120 in corner region 122 is at least substantially symmetrical with respect to inside corner 124 and outside corner 126. In contrast, the curved portion of predicted resulting geometry 108 in corner region 122 is asymmetrical with respect to inside corner 124 and outside corner 126. In particular, the curvature of an inside corner 124 of predicted resulting geometry 108 is less sharp (or less acute), while the curvature of an outside corner 124 of predicted resulting geometry 108 is sharper (or more acute) as compared with the symmetrical curve of conventional predicted geometry 120. In certain situations, this asymmetrical curve more accurately approximates the curve of the actual geometry that would be formed in patterned layer 58 of photomask 52 by the etching of patterned layer 58, as compared with prior simulated geometries, such as conventional predicted geometry 120, for example.

FIG. 8 is a detailed view of a second corner region 130 of the comparison between predicted resulting geometry 108 and conventional predicted geometry 120 shown in FIG. 6. As shown in FIG. 8, the curved portion of predicted resulting geometry 108 in corner region 130 is less sharp (or less acute) than the curved portion of conventional predicted geometry 120 in corner region 130. In certain situations, the curved portion of predicted resulting geometry 108 in corner region 130 more accurately approximates the curve of the actual geometry that would be formed in patterned layer 58 of photomask 52 by the etching of patterned layer 58, as compared with prior simulated geometries, such as conventional predicted geometry 120, for example.

FIG. 9 illustrates an example system 200 for predicting a resulting geometry (e.g., predicted resulting geometry 108 discussed herein) that will be formed in patterned layer 58 of photomask 52 based on a particular geometry defined by a mask pattern file in accordance with a particular embodiment of the disclosure. System 200 may include processor 202 and memory 204, which may be operable to store simulation software application 206 and/or mask pattern files 208. Simulation software application 206 may include any suitable software for performing any or all of the functions discussed herein for predicting geometries formed in a patterned layer of a photomask, such as the methods for generating predicted resulting geometry 108 discussed herein with reference to FIGS. 5A-5C. Mask pattern files 208 may include any one or more computer-readable files including data defining geometries to be formed in a patterned layer of a photomask and/or data defining such geometries for simulation or other testing.

Processor 202 may include any one or more suitable processors that may execute simulation software application 206 or other computer instructions in order to perform all or portions of the methods discussed herein for predicting geometries formed in a patterned layer of a photomask, such as the methods for generating predicted resulting geometry 108 discussed herein with reference to FIGS. 5A-5C. For example, processor 202 may include any suitable processor that executes simulation software application 206 to simulate or otherwise process geometries defined by one or more mask pattern files 208 in order to predict the resulting geometries that would actually be formed in a patterned layer of an actual photomask if such geometries were used as input for forming the patterned layer (e.g., if such geometries were used as input by an imaging tool).

In some embodiments, processor 202 may include a central processing unit (CPU) or other microprocessor, and may include any suitable number of processors working together. Memory 204 may include one or more memory devices suitable to facilitate execution of simulation software application 206 or other computer instructions, such as, for example, one or more random access memories (RAMs), read-only memories (ROMs), dynamic random access memories (DRAMs), fast cycle RAMs (FCRAMs), static RAM (SRAMs), field-programmable gate arrays (FPGAs), erasable programmable read-only memories (EPROMs), electrically erasable programmable read-only memories (EEPROMs), microcontrollers, or microprocessors.

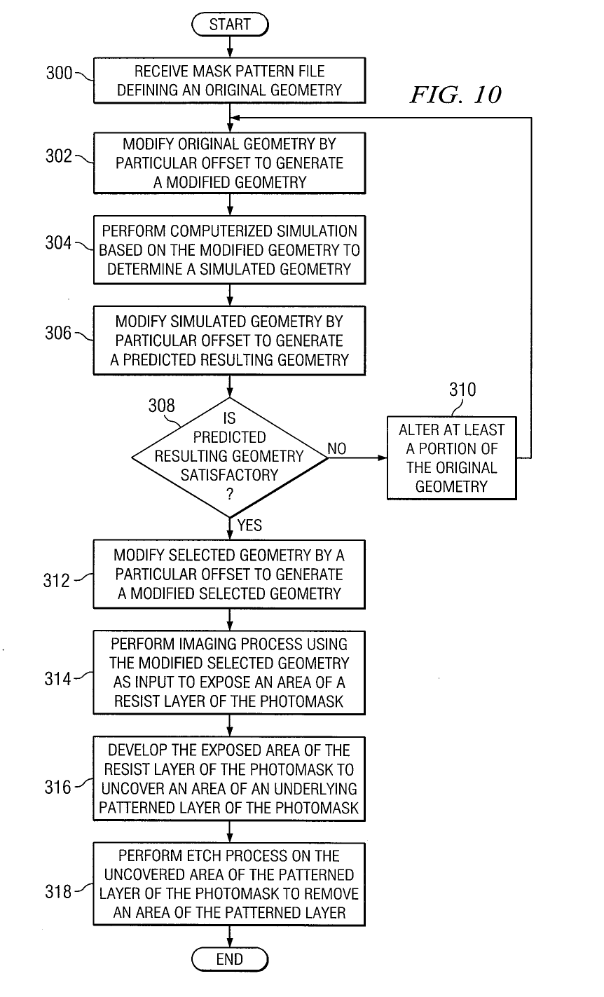

FIG. 10 illustrates a method for forming patterned layer 58 in a photomask 52 according to one embodiment of the present disclosure. At step 300, a mask pattern file 208 defining an original geometry (e.g., desired geometry 100) may be received. At step 302, the original geometry may be modified by a particular offset extending around (and within) the perimeter of desired geometry 100 to generate a modified geometry (e.g., modified geometry 102). As discussed above, the distance of the offset may be determined based on an expected distance of over-etch associated with an etch process that may be used to form the geometry in patterned layer 58 during the formation of photomask 52.

After generating the modified geometry offset from the original geometry, a computerized simulation based on the modified geometry may be performed at step 304 to determine a simulated geometry (e.g., simulated geometry 106). The simulated geometry may comprise a simulated prediction of the geometry that would be written onto photomask 52 if the modified geometry was used as input by a pattern-imaging tool. For example, such simulation may attempt to predict corner-rounding and/or other effects associated with imaging the modified geometry. As discussed above, the simulation may include any one or more suitable algorithms or modeling functions, such as one or more Gaussian functions or expressions, for example.

After the simulated geometry has been generated, the simulated geometry may be modified at step 306 to generate a prediction of the geometry that would be formed in patterned layer 58 of photomask 52 if photomask 52 were processed using the modified geometry as input for imaging the resist layer of the photomask blank used to create photomask 52 (e.g., predicted resulting geometry 108). In other words, the predicted resulting geometry may comprise a prediction of the geometry that would be formed in patterned layer 58 if an etch process was performed on an area of patterned layer 58 defined by the simulated geometry determined at step 304. Thus, the predicted resulting geometry may account for the geometric offset predicted to result due to over etching if the simulated geometry were etched into patterned layer 58.

At step 308, it may be determined whether the predicted resulting geometry determined at step 306 is satisfactory. For example, it may be determined whether particular features will be cut off or unacceptably misshaped, e.g., due to corner rounding, etc. If the predicted resulting geometry determined at step 306 is unsatisfactory, at least a portion the original geometry defined in mask pattern file 208 may be altered at step 310 based on the predicted resulting geometry determined at step 306. For example, if the predicted resulting geometry indicates that a particular feature will be cut off or unacceptably misshaped (e.g. due to corner rounding, etc.), the original geometry may be altered accordingly. Steps 302-308 may then be repeated to determine the predicted resulting geometry corresponding to the altered geometry determined at step 310. This process may be repeated in an iterative manner until it is determined at step 308 that the predicted resulting geometry is satisfactory.

After it is determined that the predicted resulting geometry is satisfactory at step 308, the original geometry or altered original geometry (if one or more alterations were made as discussed above) corresponding with the satisfactory predicted resulting geometry may be used for forming the patterned layer 58 of a photomask 52. For the purposes of this discussion, this original geometry or altered original geometry corresponding with the satisfactory predicted resulting geometry may be referred to as the “selected geometry.” At step 312, the selected geometry may be modified by a particular offset extending along (and within) the perimeter of the selected geometry to generate a modified selected geometry. Again, the distance of the offset may be determined based on an expected distance of over-etch associated with an etch process that may be used to form the geometry in patterned layer 58 during the formation of photomask 52. Thus, if the selected geometry is the original geometry defined in the mask pattern file 208 (e.g., if the original geometry was not altered at step 310), the modified selected geometry may be the same as the modified geometry determined at step 302.

At step 314, an imaging process may be performed using the modified selected geometry as input to expose an area of the resist layer of the photomask blank used to create photomask 52. In some situations, the geometry of the exposed area may be substantially similar to the simulated geometry determined at step 304. At step 316, the exposed area of the resist layer may be developed and removed to uncover an area of the underlying absorber layer of the photomask blank. The geometry of the uncovered area of absorber layer may be substantially similar to the geometry exposed by the imaging process at step 314. At step 318, one or more etch processes may be performed on the uncovered area of absorber layer (e.g., through the open area in the resist layer above the uncovered area of absorber layer) to remove an area of the absorber layer in order to form patterned layer 58 of photomask 52. Due to the effects of over-etch, the actual area of the absorber layer removed by the etch process may be larger than area of absorber layer that was uncovered at step 316. In some situations, the geometry of the actual area of the absorber layer removed by the etch process may be substantially similar to the predicted resulting geometry determined to be satisfactory at step 308.

Although the disclosed embodiments have been described in detail, it should be understood that various changes, substitutions and alterations can be made to the embodiments without departing from their spirit and scope.

What is claimed is:

1. A method of analyzing photomask geometries, comprising:
receiving an original geometry to be formed in an absorber layer of a photomask blank;
modifying the original geometry to generate a modified geometry, the modified geometry including a geometry offset from the original geometry in at least one direction;
performing a simulation based on the modified geometry to determine a simulated geometry, the simulated geometry including a simulated prediction of a geometry that would be imaged onto a resist layer of the photomask blank if the modified geometry was used as input for imaging the resist layer; and
modifying the simulated geometry to generate a predicted original geometry, the predicted original geometry including a prediction of a geometry that would be formed in the absorber layer of the photomask blank if an etch process was performed on an area of the absorber layer defined by the simulated geometry.

2. The method of claim 1, wherein:
the original geometry comprises a first perimeter; and
the modified geometry comprises a second perimeter that is offset from the first perimeter of the original geometry by a particular distance such that the second perimeter is located within the first perimeter.

3. The method of claim 2, wherein the second perimeter is offset from the first perimeter of the original geometry completely around the first perimeter by the particular distance.

4. The method of claim 2, wherein the particular distance of the offset between the second perimeter and the first perimeter is determined based on a known distance of over-etch associated with an etch process used during photomask formation.

5. The method of claim 1, wherein performing the simulation based on the modified geometry to determine the simulated geometry comprises using one or more Gaussian functions.

6. The method of claim 1, wherein performing the simulation based on the modified geometry to determine the simulated geometry comprises approximating geometric distortion associated with imaging the modified geometry into the resist layer of the photomask blank.

7. The method of claim 1, wherein modifying the simulated geometry to generate the predicted original geometry comprises generating a geometry that is offset from the simulated geometry in at least one direction.

8. The method of claim 7, wherein:
the simulated geometry comprises a first perimeter; and
the predicted original geometry comprises a second perimeter that is offset from the first perimeter of the simulated geometry by a particular distance such that the first perimeter is located within the second perimeter.

9. The method of claim 8, wherein the second perimeter of the predicted original geometry is offset from the first perimeter of the simulated geometry completely around the first perimeter by the particular distance.

10. The method of claim 8, wherein the particular distance of the offset between the second perimeter and the first perimeter is determined based on a known distance of over-etch associated with an etch process used during the processing of the absorber layer of the photomask blank.

11. The method of claim 7, wherein:
the original geometry comprises a first perimeter;
the modified geometry comprises a second perimeter that is offset from the first perimeter of the original geometry by a particular distance such that the second perimeter is located within the first perimeter;
the simulated geometry comprises a third perimeter; and
the predicted original geometry comprises a fourth perimeter that is offset from the third perimeter of the simulated geometry by the particular distance such that the third perimeter is located within the fourth perimeter.

12. The method of claim 1, wherein:
the original geometry includes a particular portion having an inside corner and an outside corner, wherein the outside corner is symmetric with respect to the inside corner; and
the predicted original geometry comprises a curved portion corresponding with the particular portion of the original geometry, the curved portion of the predicted original geometry being asymmetric with respect to the inside corner and the outside corner.

13. The method of claim 1, wherein:
the original geometry includes a first linear portion; and
the predicted original geometry comprises a second linear portion corresponding with and substantially co-located with the first linear portion of the original geometry.

14. The method of claim 1, further comprising altering at least a portion of the original geometry based on the determined predicted original geometry.

15. (canceled)

16. The method of claim 1, wherein the simulated geometry comprises a simulated prediction of a geometry that would be imaged onto the resist layer of the photomask blank if the modified geometry was used as input by a pattern-imaging tool.

17. The method of claim 1, wherein the predicted original geometry comprises a prediction of a geometry that would be formed in the absorber layer of the photomask blank if the modified geometry were used as input for forming a patterned layer in the absorber layer of the photomask blank.

18. (canceled)

19. A method of forming a photomask, comprising:
receiving an original geometry to be formed in an absorber layer of a photomask blank;
modifying the original geometry to generate a modified geometry, the modified geometry including a geometry offset from the original geometry in at least one direction;
performing a simulation based on the modified geometry to determine a simulated geometry, the simulated geometry including a simulated prediction of a geometry that would be written into a resist layer of the photomask blank if the modified geometry was used as input for imaging the resist layer;
modifying the simulated geometry to generate a predicted original geometry, the predicted original geometry including a prediction of a geometry that would be formed in the absorber layer of the photomask blank if an etch process was performed on an area of the absorber layer defined by the simulated geometry;
altering at least a portion the original geometry based on the generated predicted original geometry;
using the altered original geometry as input for exposing one or more portions of the resist layer of the photomask blank;
developing the one or more exposed portions of the resist layer of the photomask blank to uncover one or more portions of the absorber layer of the photomask blank; and
performing an etch process to remove the one or more uncovered portions of the absorber layer of the photomask blank to form a patterned layer.

20. (canceled)

21. A system for analyzing photomask geometries, comprising:
a computer system having a processor; and
a computer-readable medium coupled to the computer system, the computer-readable medium including software, when executed by the processor, operable to:
receive an original geometry to be formed in an absorber layer of a photomask blank;
modify the original geometry to generate a modified geometry, the modified geometry including a geometry offset from the original geometry in at least one direction;
perform a simulation based on the modified geometry to determine a simulated geometry, the simulated geometry including a simulated prediction of a geometry that would be written into a resist layer of the photomask blank if the modified geometry was used as input for imaging the resist layer; and
modify the simulated geometry to generate a predicted original geometry, the predicted original geometry including a prediction of a geometry that would be formed in the absorber layer of the photomask blank if an etch process was performed on an area of the absorber layer defined by the simulated geometry.

22. The method of claim 19, wherein:
the original geometry comprises a first perimeter; and
the modified geometry comprises a second perimeter that is offset from the first perimeter of the original geometry by a particular distance such that the second perimeter is located within the first perimeter.

23. The method of claim 19, wherein:
modifying the simulated geometry to generate the predicted original geometry comprises generating a geometry that is offset from the simulated geometry in at least one direction;
the simulated geometry comprises a first perimeter; and
the predicted original geometry comprises a second perimeter that is offset from the first perimeter of the simulated geometry by a particular distance such that the first perimeter is located within the second perimeter.

24. The system of claim 21, wherein:
the original geometry comprises a first perimeter; and
the modified geometry comprises a second perimeter that is offset from the first perimeter of the original geometry by a particular distance such that the second perimeter is located within the first perimeter.

25. The system of claim 21, wherein:
the software modifies the simulated geometry to generate the predicted original geometry by generating a geometry that is offset from the simulated geometry in at least one direction;
the simulated geometry comprises a first perimeter; and
the predicted original geometry comprises a second perimeter that is offset from the first perimeter of the simulated geometry by a particular distance such that the first perimeter is located within the second perimeter.

26. The system of claim 21, further comprising the software operable to alter at least a portion of the original geometry based on the determined predicted original geometry.
